(19) United States
(12) Patent Application Publication
(10) Pub. No.: US 2020/0265647 A1
(43) Pub. Date: Aug. 20, 2020

(54) Augmented Reality-Based Lighting System Design And Commissioning

(71) Applicant: Eaton Intelligent Power Limited, Dublin 4 (IE)

(72) Inventors: Nam Chin Cho, Peachtree City, GA (US); Deborah Baus, Peachtree City, GA (US); Parth Joshi, Atlanta, GA (US); B. Glenn Siegel, Peachtree City, GA (US); Christopher Lee Bohler, Peachtree City, GA (US)

(21) Appl. No.: 16/785,497

(22) Filed: Feb. 7, 2020

Related U.S. Application Data
(60) Provisional application No. 62/807,175, filed on Feb. 18, 2019.

(51) Int. Cl. G06T 19/00; G06T 19/20; G01K 1/02; G06T 15/50; G06T 17/00; G06F 30/13

(52) U.S. Cl. CPC G06T 19/006; G06T 19/20; G01K 1/024; G06T 2210/04; G06T 17/00; G06F 30/13; G06T 15/50

(57) ABSTRACT

An augmented reality-based method for determining locations of lighting devices includes displaying on a display screen, by an augmented reality device, a real-time image of a target physical area. The real-time image includes lighting devices that are installed in the physical area. The method further includes displaying on the display screen, by the augmented reality device, a first marker and a second marker. The first marker is displayed overlaid on a first lighting device of the lighting devices, and the second marker is displayed overlaid on a second lighting device of the lighting devices. The method also includes determining, by the augmented reality device, a location of the first marker and a location of the second marker.

### CROSS REFERENCE TO RELATED APPLICATIONS

The present application claims priority under 35 U.S.C. Section 119(e) to U.S. Provisional Patent Application No. 62/807,175, filed Feb. 18, 2019 and titled “Augmented Reality-Based Lighting System Design And Commissioning,” the entire content of which is incorporated herein by reference

### TECHNICAL FIELD

The present disclosure relates generally to lighting systems, and more particularly to using augmented reality in determining locations of lighting devices and IoT devices and in designing and commissioning lighting systems.

### BACKGROUND

A lighting system may include lighting devices such as lighting fixtures, wall stations, sensors, receptacles, etc. After a lighting system of lighting devices is installed in a space (e.g., a residential or commercial building, a parking lot or garage, etc.), the lighting system generally needs to be commissioned before the space is opened for regular use. The commissioning of a lighting system may include grouping of lighting devices, configuring operations of lighting fixtures, etc. For example, lighting devices may be grouped such that, for example, operations of some of the lighting fixtures are controlled by a particular one or more wall stations and/or one or more sensors. As another example, operations of lighting fixtures may be configured to set lighting characteristics such as brightness levels, etc. In many cases, location information of installed lighting devices can be used to properly and efficiently commission lighting systems. The location information can also be used to generate a floor plan that includes the locations of installed lighting devices. Thus, a solution that enables locations of lighting devices to be reliably and accurately determined is desirable. Further, a solution that enables the generation of a floor plan of a space including the locations of lighting devices is desirable. Further, a solution that enables at least some parts of the commissioning process to be performed remotely is desirable. Further, a solution that enables augmented reality models of lighting devices to be overlaid on a real-time image of a space based on information received from a remote device is desirable.

### SUMMARY

The present disclosure relates generally to lighting systems, and more particularly to using augmented reality in determining locations of lighting devices and IoT devices and in designing and commissioning lighting systems. In an example embodiment, an augmented reality-based method for determining locations of lighting devices includes displaying on a display screen, by an augmented reality device, a real-time image of a target physical area. The real-time image includes lighting devices that are installed in the physical area. The method further includes displaying on the display screen, by the augmented reality device, a first marker and a second marker. The first marker is displayed overlaid on a first lighting device of the lighting devices, and the second marker is displayed overlaid on a second lighting device of the lighting devices. The method also includes determining, by the augmented reality device, a location of the first marker and a location of the second marker.

In another example embodiment, an augmented reality-based method for commissioning a lighting system includes displaying on a display screen, by an augmented reality device, a real-time image of a target physical area that includes lighting devices. The method further includes transmitting, by the augmented reality device, the real-time image of the target physical area, location information of the lighting devices, and spatial information of the target physical area to a remote commissioning device. The method also includes performing, by the remote commissioning device, lighting system commissioning of the lighting system based on the commissioning information.

In another example embodiment, an augmented reality-based lighting design method includes receiving, by an augmented reality device, identification information of a lighting device from a remote device. The method further includes receiving, by the augmented reality device, location information from the remote device. The method also includes displaying, by the augmented reality device, a 3-D model of the lighting device on a display screen of the augmented reality device, where the 3-D model is overlaid on a real time image of a physical area at a location indicated by the location information.

These and other aspects, objects, features, and embodiments will be apparent from the following description and the appended claims.

### BRIEF DESCRIPTION OF THE FIGURES

Reference will now be made to the accompanying drawings, which are not necessarily drawn to scale, and wherein:

FIG. 1 illustrates a lighting system of lighting devices according to an example embodiment;

FIGS. 2A and 2B illustrate an augmented reality (AR) device that can be used in determining locations of lighting devices of the lighting system and in the commissioning of the lighting system according to an example embodiment;

FIGS. 2C and 2D illustrate augmented reality devices that can be used in determining locations of lighting devices of the lighting system and in the commissioning of the lighting system according to another example embodiment;

FIG. 3 illustrates a block diagram of the augmented reality devices of FIGS. 2A and 2B according to an example embodiment;

FIG. 4 illustrates a real-time image of a physical area displayed on the AR device of FIG. 2A incorporating a lighting AR application according to an example embodiment;

FIG. 5 illustrates a real-time image of the physical area of FIG. 4 displayed on the AR device of FIG. 2A along with a list of lighting device markers according to an example embodiment;

FIG. 6 illustrates a real-time image of the physical area of FIG. 4 displayed on the AR device of FIG. 2A showing lighting device markers overlaid on the lighting devices according to an example embodiment;

FIG. 7 illustrates a floor plan generated based on locations of lighting devices and other objects and structures as determined by the AR device of FIG. 2A according to an example embodiment;

FIG. 8 illustrates a system for remote commissioning of the lighting system of FIG. 1 according to an example embodiment;

FIG. 9 illustrates a method of determining locations of lighting devices using an AR device according to an example embodiment;

FIG. 10 illustrates a method of commissioning a lighting system according to an example embodiment;

FIG. 11 illustrates a method of commissioning a lighting system according to an example embodiment;

FIG. 12 illustrates an augmented reality-based lighting design system according to an example embodiment; and

FIG. 13 illustrates an augmented reality-based lighting design method according to an example embodiment.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different drawings may designate like or corresponding, but not necessarily identical elements.

### DETAILED DESCRIPTION OF THE EXAMPLE EMBODIMENTS

In the following paragraphs, example embodiments will be described in further detail with reference to the figures. In the description, well-known components, methods, and/or processing techniques are omitted or briefly described. Furthermore, reference to various feature(s) of the embodiments is not to suggest that all embodiments must include the referenced feature(s).

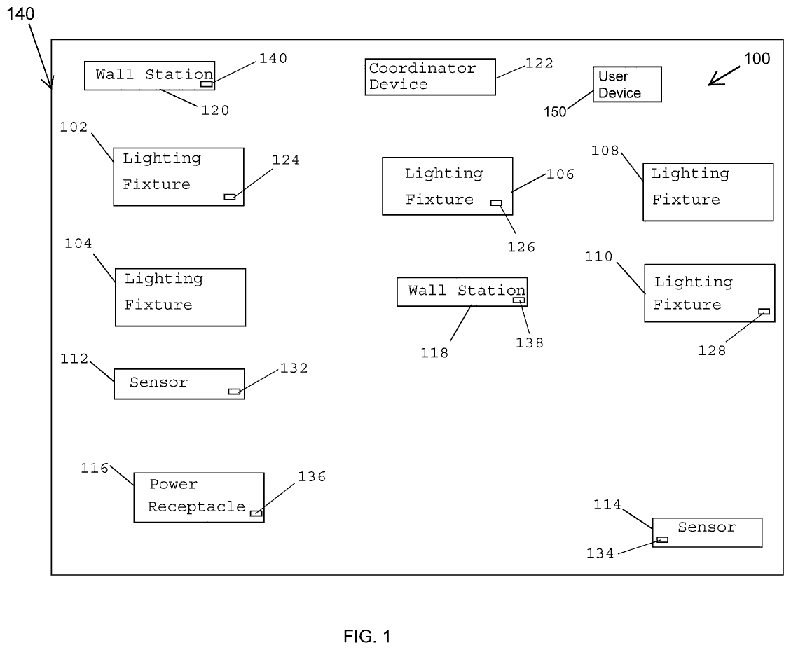

Turning now to the figures, particular example embodiments are described. FIG. 1 illustrates a lighting system 100 of lighting devices according to an example embodiment. As illustrated in FIG. 1, the lighting system 100 may include a number of lighting/IoT devices (referred to herein as lighting devices). For example, the lighting system 100 may include a number of lighting devices 102-120 and a coordinator device 122. To illustrate, the system 100 may include lighting fixtures 102-110, sensors 112, 114, and a controllable power receptacle 116, and wall stations 118, 120. Each lighting device 102-120 may be capable of wirelessly communicating with or through the coordinator device 122. Alternatively or in addition, each lighting device 102-120 may be capable of wirelessly communicating directly with other devices.

To illustrate, the lighting devices 102-120 and the coordinator device 122 may each include a transceiver that is used for wireless communications as can be readily understood by those of ordinary skill in the art. For example, the lighting devices 102-122 may transmit and receive wireless signals that are compliant with one or more wireless communication standards such as Wi-Fi, Bluetooth LE, Thread, ZigBee, or a proprietary communication standard.

In some example embodiments, when the lighting system 100 is powered up, each of the lighting devices 102-120 may be paired with the coordinator device 122, establishing wireless communications between the individual lighting devices and the coordinator device 122. Each lighting device 102-120 may transmit lighting device identification information (e.g., a serial number, a network address, etc.) that uniquely identifies the particular lighting device. The identification information of the lighting devices may already be known to the coordinator device 122, for example, from the installation contractor that installed the lighting devices 102-120.

In some example embodiments, the coordinator device 122 may include default configurations and settings that are used to control the lighting devices 102-120 of the lighting system 100. Subsequent to the initial power-up, the default configurations and settings can be changed by a user, for example, during the commissioning of the lighting system 100. A user may first determine the locations of the lighting devices 102-120 of the lighting system 100 to properly commission the lighting system 100.

In some example embodiments, a person may use a user device 150 to control operations of the lighting devices 102-120 as part of the commissioning of the lighting system 100. For example, the user device 150 may communicate with the lighting devices 102-120 directly and/or through the coordinator device 122. The user device 150 may be a mobile phone, a tablet, a laptop that can execute software applications such as lighting control applications, augmented reality (AR) applications, etc.

In some example embodiments, the identification information (e.g., serial number, network address, etc.) of the lighting devices 102-120 may be used to determine the locations of the lighting devices 102-120. For example, a list of serial numbers and/or network addresses of the lighting devices 102-120 may be known to the installation contractor that installed the lighting devices. Serial numbers and/or network addresses of the lighting devices 102-120 may also be determined from beacon or other signals transmitted by the lighting devices. The lighting device identification information may be stored in or accessible to the user device 150 for use in controlling and/or commissioning the lighting system 100.

In some example embodiments, a user may use the user device 150 to execute a lighting control application to manually determine and record the locations of the lighting devices 102-120 in association with the identification information of the lighting devices 102-120. For example, a user may walk around the space 140 while selecting individual lighting devices using a lighting control software code or application that is executed by the user device 150. The user may record the locations of the individual lighting devices in the user device 150 as selected lighting devices individually respond to the lighting control message/command from the user device 150. For example, the user may record the locations of the lighting devices 102-120 in association with the identification information of the lighting devices 102-120.

In some example embodiments, instead of or in additional to manually recording the locations of the lighting devices 102-120, a user may use the user device 150 to execute an augmented reality (AR) application to determine and record the locations of the lighting devices 102-120 in association with the identification information of the lighting devices 102-120 as described below. For example, using the user device 150, a user may overlay virtual markers on respective lighting devices of the lighting system 100 displayed on the display screen of the user device 150. Each virtual marker may be an icon (or another display representation) that is already associated with the identification information of an individual lighting device 102-120. The user device 150 may execute the AR application to determine the locations of the virtual markers, which correspond to the locations of the respective lighting devices. In some example embodiments, other applications and/or software components in the user device 150 may be integrated in the AR application or may interface with the AR application.

In some example embodiments, after the locations of the lighting devices 102-120 are determined, a user (e.g., a commissioning expert) may perform the commissioning of the lighting system 100 by making use of the location information of the lighting devices 102-120. For example, a commissioning expert may use the information to walk around the space 140 while commissioning the lighting system 150. For example, during commissioning, the system 100 may be configured such that the wall station 118 controls the lighting fixtures 102, 104, and such that the wall station 120 controls the lighting fixtures 106-110. The system 100 may be configured such that one or more of the wall stations 118, 120 controls other lighting devices of the lighting system 100 such as the sensors 112, 114, the power receptacle 116, and/or the sensors 124-128. The system 100 may also be configured such that one or more of the lighting fixtures 102-110 are controlled based on motion and/or other (e.g., ambient light, etc.) detections by one or more of the sensors 112, 114, 124-128.

In some alternative embodiments, a remotely located commissioning expert may use a real-time image of at least a portion of the space 140, the location information of the lighting devices 102-120, and spatial information (e.g., the height of a ceiling, locations of walls, etc.) of the space 140 determined by the user device 150 to remotely commission the lighting system 100. To illustrate, the user device 150 may include a camera that captures the real time image of the space 140, and the user device 150 may provide the real time image to a remote device (e.g., a laptop, a tablet, etc.) of the remotely located commissioning expert. The user device 150 may provide the location information of the lighting devices 102-120 in association with the identification information of the lighting devices 102-120. The user device 150 may execute AR modules (e.g., HoloToolkit modules) to perform spatial mapping to identify the surfaces (e.g., floor, ceiling, walls, etc.) and determine relevant information such as the height of a ceiling that is provided to the remote commissioning expert. The remotely located commissioning expert may use the information provided by the user device 150 to determine illuminance values based on intensity values extracted from photometric data files associated with the individual lighting devices 102-120. Alternatively, the user device 150 may execute software code to determine the

In some example embodiments, after the locations of the lighting devices 102-120 are determined, a user may also generate a floor plan that shows the locations of the lighting devices 102-120. For example, the locations of the lighting devices 102-120 may be added to a separately generated floor plan that shows objects (e.g., walls, doors, windows, stairs, furniture, etc.) that are in the space 140.

In some example embodiments, after the locations of the lighting devices 102-120 are determined, a user may also generate a floor plan based on the locations of the lighting devices 102-120 as well as size and location information of other objects (e.g., walls, doors, windows, stairs, furniture, etc.) in the space 140. For example, the size and location information of other objects may be determined by the user device 150 by executing AR operations (e.g., spatial mapping) and/or artificial intelligence applications that identify objects, surfaces, etc.

In some example embodiments, the lighting system 100 may include more or fewer lighting devices than shown. In some example embodiments, the lighting devices of the lighting system 100 may be located in a different configuration than shown without departing from the scope of this disclosure.

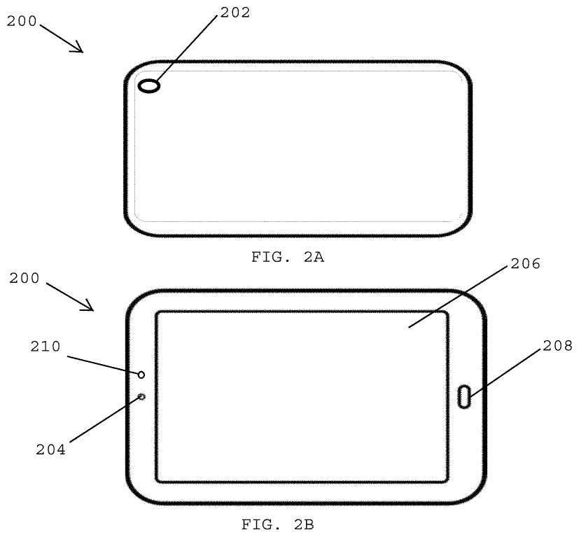

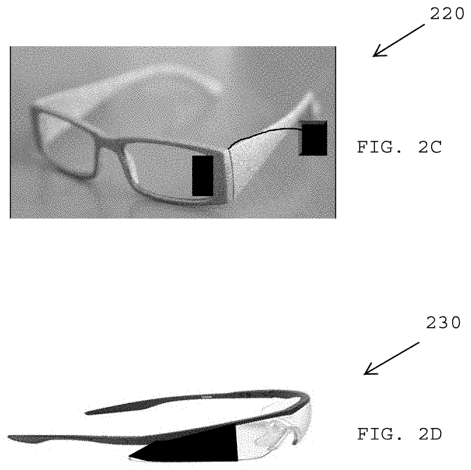

FIGS. 2A and 2B illustrate an augmented reality (AR) device 200 that can be used in determining locations of lighting devices of the lighting system 100 and in the commissioning of the lighting system 100 according to an example embodiment. FIG. 2A illustrates a back side of the AR device 200, and FIG. 2B illustrates the front side of the AR device 200. For example, the augmented reality device 200 may be a tablet, a smartphone, etc. Alternatively, the augmented reality device 200 may be a headset, glasses, goggles, or another type of device with an augmented reality capable display. In some example embodiments, the AR device 200 may correspond to the user device 150 of FIG. 1.

Referring to FIGS. 1, 2A and 2B, in some example embodiments, the AR device 200 may include a back-facing camera 202 on a back side of the augmented reality device 200. The AR device 200 may also include a viewport/display screen 206 on a front side of the augmented reality device 200. In some example embodiments, the AR device 200 may also include a front-facing camera 204, a user input area 208, an ambient light sensor 210, accelerometers, and/or other sensors useful in determining orientation and other information for use in generating and displaying an AR image on the viewport 206.

In some example embodiments, the viewport 206 may be used to display images as seen by the cameras 202, 204 as well as to display objects (e.g., icons, text, etc.) stored, received, and/or generated by the AR device 200. The viewport 206 may also be used as a user input interface for the AR device 200. For example, the viewport 206 may be a touch sensitive display screen.

In some example embodiments, an image of a physical space in front of the AR device 200 may be displayed on the viewport 206 in real time as viewed by the camera 202. For example, the AR device 200 may include an AR application that activates the camera 202 such that a real-time image of the physical space viewed by the camera 202 is displayed on the viewport 206.

In some example embodiments, the AR device 200 may include an executable AR software application that includes or activates lighting control components, AR components, and other software components used to determine locations of objects, to display images, to activate hardware components of the AR device 200, etc. In some example embodiments, the AR application may be executed by the AR device 200 to determine spatial information of a space viewable by the camera 202, 204. For example, the spatial information may include locations of a ceiling, walls, a floor, etc. and height of a ceiling, height of other objects that are in a physical space such as the space 140. In some example embodiments, the AR application may incorporate or interface with an AR software, such as ARKit, ARCore, Holokit, etc.

In some example embodiments, the AR device 200 may include a software component or application that is executable to determine the location of the AR device 200 itself and the locations of objects that are displayed on the viewport 206. To illustrate, the AR device 200 may determine the location of the AR device 200 in GPS coordinates or other location parameters (e.g., relative to a reference location in a space). For example, a virtual marker may be overlaid on a lighting fixture displayed in the viewport 206 such that the virtual marker is anchored to the particular lighting fixture, and the AR device 200 may determine the location of the virtual marker, thereby determining the location of the particular lighting fixture. The AR device 200 may store and/transmit the location information of the lighting fixture for use in commissioning, floor plan generation, etc.

FIGS. 2C and 2D illustrate AR devices 220, 230 that can be used in determining locations of lighting devices of the lighting system 100 and in the commissioning of the lighting system 100 according to another example embodiment. In some example embodiments, the AR device 220 may be used to perform the operations described above with respect to the AR device 200. For example, the glass screens of the devices 220, 230 may be used as display screens similar to the viewport 206 of the AR device 200. In some example embodiments, another AR device may be used to perform the operations performed by the AR device 200 in a similar manner as described above with respect to FIGS. 2A and 2B. Although the descriptions of other figures are presented generally with respect to the AR device 200 of FIGS. 2A and 2B, the description is equally applicable to the AR devices 220, 230 of FIGS. 2C and 2D.

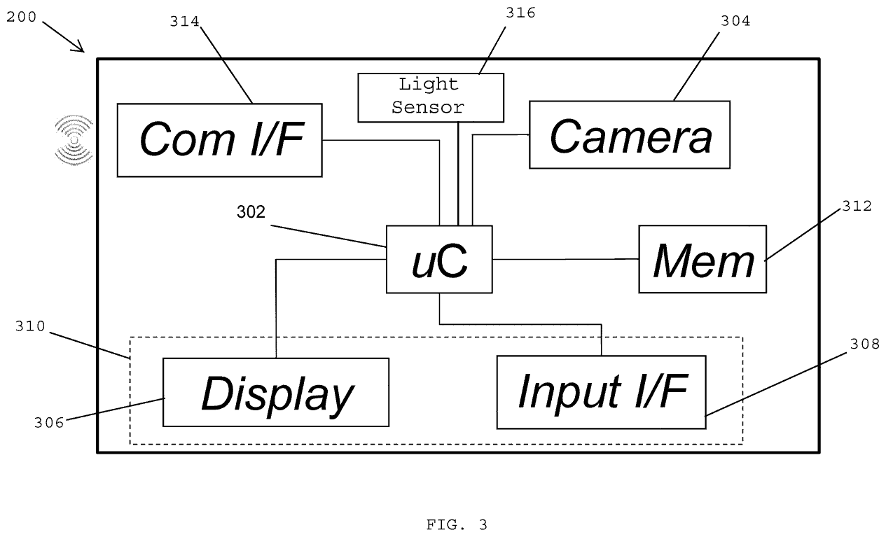

FIG. 3 illustrates a block diagram of the augmented reality device 200 of FIGS. 2A and 2B according to an example embodiment. In some example embodiments, the block diagram shown in FIG. 3 may correspond to the augmented reality devices 220, 230 of FIGS. 2C and 2D. Referring to FIGS. 2A, 2B, and 3, in some example embodiments, the AR device 200 includes a controller 302, a camera component 304, a display component 306, an input interface 308, a memory device 312, and a communication interface 314. For example, the camera component 304 may correspond to or operate with the cameras 202, 204. The display component 306 may correspond to or may be part of the viewport/display screen 206 and may include circuitry that enables or performs the displaying of information (e.g., images, text, etc.) on the viewport 206. The input interface 308 may correspond to the user input area 208 and/or the user input components of the viewport 206. The communication interface 314 may be used for communication, wirelessly or via a wired connection, by the AR device 200.

The controller 302 may include one or more microprocessors and/or microcontrollers that can execute software code stored in the memory device 312. For example, the software code of an AR application may be stored in the memory device 312 or retrievable from a remote storage location (e.g., cloud service or remotely located server or database) via the communication interface 314 or via other communication means. Other executable software codes used in the operation of the AR device 200 may also be stored in the memory device 312 or in another memory device of the AR device 200. For example, artificial intelligence and/or other software codes may be stored in the memory device 312 as part of the AR application or along with the AR application and may be executed by the controller 302.

In general, the one or more microprocessors and/or microcontrollers of the controller 302 execute software code stored in the memory device 312 or in another device to implement the operations of the AR device 200 described herein. In some example embodiments, the memory device 312 may include a non-volatile memory device and volatile memory device. In some example embodiments, data that is used or generated in the execution of AR application(s) and other code may also be retrieved and/or stored in the memory device 312 or in another memory device of the AR device 200 or retrieved from a remote storage location (e.g., cloud service or remotely located server or database) via the communication interface 314 or other communication means. For example, photometric data files (e.g., IES files) corresponding to the lighting fixtures may be stored in and retrieved from the memory device 312.

In some example embodiments, the lighting design AR application stored in the memory device 312 may incorporate or interface with an augmented reality application/software, such as ARKit, ARCore, HoloLens, etc., that may also be stored in the memory device 312 or called upon from or provided via a remote storage location (e.g., cloud service or remotely located server or database) via the communication interface 314 or other communication means.

The controller 302 may communicate with the different components of the AR device 200, such as the camera component 304, etc., and may execute relevant code, for example, to display a real-time image as viewed by the camera 202 and/or 304 as well as other image objects on the viewport 206.

Although the block diagram of FIG. 3 is described above with respect to the AR device 200, the block diagram and the above description are equally applicable to the AR devices 220, 230 of FIGS. 2C and 2D. In some example embodiments, the AR device 200 includes other components than shown without departing from the scope of this disclosure. In some example embodiments, the AR device 200 may include more or fewer components or a different configuration of components than shown without departing from the scope of this disclosure.

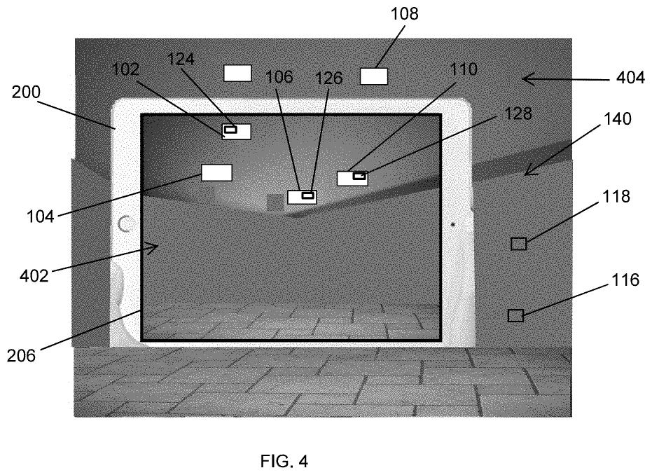

FIG. 4 illustrates a real-time image 402 of the space 140 displayed on the viewport 206 of the AR device 200 according to an example embodiment. Referring to FIGS. 1-4, in some example embodiments, the AR device 200 may execute an AR software application that uses the camera 202 to display the real-time image 402 on the viewport 206. The real-time image 402 displayed in the view port 206 may include the lighting fixtures 102, 104, 106, 110 of the lighting system 100 shown in FIG. 1. Other lighting devices such as the wall station 118, and the power receptacle 116, are outside of the view of the camera of the AR device 200 as shown in FIG. 4 but may be brought into view by changing the orientation and/or direction of the AR device 200.

In some example embodiments, lighting device identification information, such as serial numbers, network addresses, etc., of the lighting devices may already be stored in the AR device 200 as described above. However, a user of the AR device 200 may not yet know which identification information corresponds to which lighting device.

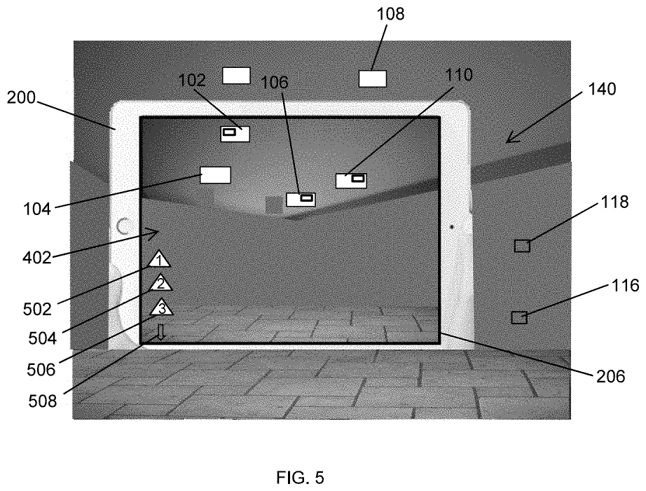

FIG. 5 illustrates a real-time image 402 of the space 140 displayed on the viewport 206 of the AR device 200 along with a list of lighting device markers according to an example embodiment. Referring to FIGS. 1-5, in some example embodiments, lighting device markers 502, 504, 506 may be displayed in the viewport 206 of the AR device 200 for selection by a user. Additional lighting device markers may be accessed or displayed by selecting the arrow 508. The lighting device markers 502-506 may be labeled icons as shown in FIG. 5. Alternatively, the markers 502-506 may be images only, text only, different shape icons, etc. without departing from the scope of this disclosure.

In some example embodiments, the lighting device markers 502-506 and others that may be displayed on the viewport 206 may each be associated with a respective lighting device of the lighting system 100 shown in FIG. 1. For example, each lighting device marker may be associated with a respective lighting device of the lighting system 100 based on the serial number of the lighting device, a wireless network address, or another identifier that uniquely identifies the lighting device.

In some example embodiments, a user may identify a lighting device in the space 140 that corresponds to a particular lighting device marker displayed in the viewport 206 by selecting the particular lighting device marker. For example, if the lighting device marker 502 is associated with the lighting device 102, the AR device 200 may send a lighting message/command to the lighting device 102 in response to a user selecting the lighting device marker 502 in the viewport 206. In response, the lighting device 102 may, for example, turn on, turn off, or flash its light depending on the lighting message/command. By selecting the different lighting device markers including the lighting device markers 502-506 one at a time, the association between particular lighting device markers and lighting devices may be determined.

In some alternative embodiments, a user may provide an input to the lighting devices 102-120 individually, where the lighting device marker that corresponds to a particular lighting device receiving the input is identified in the viewport 206. For example, when a user flashes a light on a sensor of the lighting device 102, the lighting device marker corresponding to the lighting device 102 is highlighted or otherwise identified in the viewport 206.

In some example embodiments, a user may walk around the space 140 and record the locations of the lighting devices 102-120 after identifying the lighting devices 102-120 based the associations of the lighting device markers with the lighting devices. As each lighting device is identified as described above, a user may determine the location of the lighting device, for example, using a GPS (or indoor positioning system (“IPS”)) application or software component that is executed by the AR device 200 or by another GPS/IPS device. For example, a user, holding the AR device 200, may stand below or next to the lighting fixture 102 that is just identified and determine the location. The user may then record the location as the location of the lighting fixture 102. The user may record the location information of each lighting device 102-120 in the AR device 200 in association with the identification information of the particular lighting device 102-120.

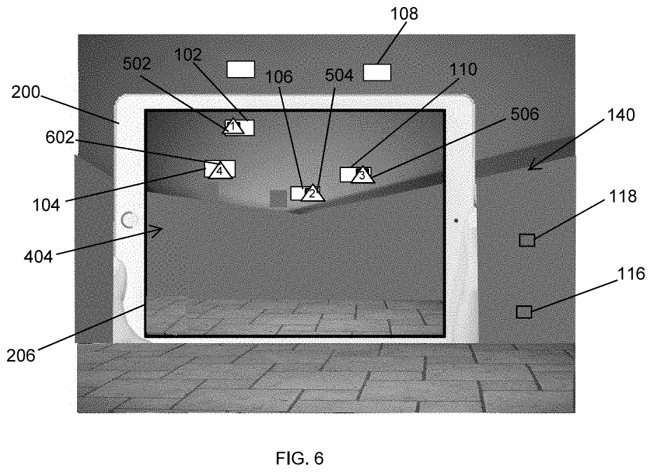

In some example embodiments, instead of manually determining and recording the locations of the lighting devices 102-120, the AR device 200 may determine and record the locations of the lighting devices 102-120 based on the lighting device markers as described with respect to the FIG. 6.

Although the lighting device markers 502-506 are shown as triangular icons, in some example embodiments, the lighting devices markers may have a different shape, format (text only), etc. without departing from the scope of this disclosure.

FIG. 6 illustrates real-time image 402 of the space 140 with lighting device markers overlaid on the lighting devices according to an example embodiment. Referring to FIGS. 1-6, in some example embodiments, after identifying a particular lighting fixture by selecting a lighting device marker as described above, the user may place the associated lighting device marker over the identified lighting device displayed in the viewport 206.

In some example embodiments, the lighting device marker 502 may be associated with the serial number and/or network id of the lighting fixture 102. The lighting device marker 602 may be associated with the serial number or network id of the lighting fixture 104. The lighting device marker 504 may be associated with the serial number or network id of the lighting fixture 106. The lighting device marker 506 may be associated with the serial number or network id of the lighting fixture 110.

In some example embodiments, the AR device 200 may send a lighting command to the lighting fixture 102 when the user selects the lighting device marker 502 as described above with respect to FIG. 5. When the lighting fixture 102 responds to the lighting command (e.g., turn on light) and the lighting fixture 102 responds (e.g., emit its light), the user may place the lighting device marker 502 on the lighting fixture 102 in the viewport 206 of the AR device 200. In some example embodiments, the user may place the lighting device marker 502 on the sensor 124 of the lighting fixture 102. The user may identify the remaining lighting devices 104-120 and place the respective lighting device markers 504, 506, 602, etc. on the lighting devices 104-120 in a similar manner. A user may move the AR device 200 such that the real time image displayed in the viewport 206 changes such that different lighting devices are included in the real time image.

In some example embodiments, the AR application executed by the AR device 200 anchors a lighting device marker that is overlaid on a lighting device displayed on the viewport 206 to the physical location of the lighting device in the space 140. For example, after the lighting device marker 502 is placed on the lighting fixture 102 in the real time image 404 displayed on the viewport 206, the lighting device marker 502 remains overlaid on the lighting fixture 102 whenever the lighting fixture 102 is displayed on the viewport 206 unless, for example, the lighting device marker 502 is moved or removed.

In some example embodiments, the AR device 200 may execute the AR application to determine the location of the lighting devices 102, 104, etc. after the lighting device markers 502, 504, 506, 602, etc. are overlaid on the lighting devices 102, 104, etc. as shown in FIG. 6. For example, the AR device 200 may determine the locations of the lighting device markers by executing distance measurement and other AR modules as can be understood by those of ordinary skill in the art with the benefit of this disclosure. Because the lighting device markers are anchored to the physical locations of the lighting devices, the locations of the lighting device markers correspond to the locations of the respective lighting devices. That is, the locations of the lighting devices may be determined by determining the locations of the lighting device markers.

In some example embodiments, the AR device 200 may store the location information of each lighting device 102-120 in association with the identification information of the particular lighting device 102-120. For example, the location information may be stored in the AR device 200.

In some example embodiments, placing lighting device markers on the sensors of the lighting devices may result in a more accurate RTLS system. For example, the lighting device marker 502 may be overlaid on the sensor 124 of the lighting fixture 102. As another example, the lighting device marker 504 may be overlaid on the sensor 126 of the lighting fixture 104. Because RTLS systems rely on the location information of sensors to determine/estimate the location of an object that transmits an RTLS signal, more accurate location information of the sensors may result in a more reliable RTLS system.

In some example embodiments, the AR device 200 may be calibrated to more accurately determine global positioning system (GPS) location of the AR device 200 prior to determining the location of the lighting device markers 502, 504, etc. For example, a GPS device may be used to provide a more accurate location information that is used to calibrate the AR device 200. The true north setting of the AR device 200 may also be calibrated prior to determining the location of the lighting device markers 502, 504, etc. For example, a compass may be used to determine a more accurate true north direction that is used to calibrate the AR device 200. The calibration of the AR device 200 may result in the AR device 200 determining the locations of the lighting devices 102-120 (based on the lighting device markers) more accurately, which enhances RTLS systems that rely on the standalone and integrated sensors of the lighting system 100.

In some example embodiments, a local commissioning expert may use the location information determined using the lighting device markers along with the identification information of the lighting devices 102-120 to properly configure/commission the lighting system 100. For example, commissioning expert may group some of the lighting fixtures with the same sensor based on the locations of the lighting fixtures and the sensor. To illustrate, the local commissioning expert may configure the coordinator device 122 such that the some of the lighting fixtures are controlled based on detection by the same sensor. As another example, the local commissioning expert may group multiple sensors with a lighting fixture based on the locations of the sensors and the lighting fixture by configuring the coordinator device 122. As another example, the local commissioning expert may set brightness level settings of multiple lighting fixtures based on the locations of the lighting fixtures by configuring the coordinator device 122. In some example embodiments, by using the lighting device markers 502, 504, etc., the locations of the lighting devices 102-120 can be more efficiently and more accurately determined, which enables more efficient and accurate commissioning of the lighting system 100.

In some example embodiments, the location information of the lighting devices 102-120 may be used to generate a floor plan showing the locations of the lighting devices 102-120. Because the location information is associated with the identification information of the lighting devices, the floor plan may indicate the locations of the lighting devices as well as the identification information of the lighting devices. To illustrate, if the lighting devices 102-120 are located as shown in FIG. 1, the AR device 200 or another device may use the identification information and the location information as determined using the lighting device markers to generate a floor plan that shows the lighting devices 102-120 at the locations shown in FIG. 1. For example, various shaped objects may be used to represent the lighting devices 102-120 in the floor plan.

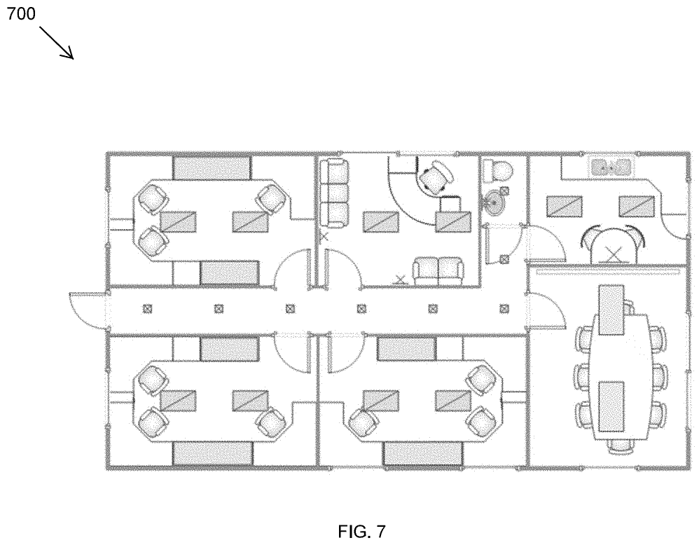

FIG. 7 illustrates a floor plan 700 generated based on locations of lighting devices and other objects and structures as determined by the AR device of FIG. 2A according to an example embodiment. Referring to FIGS. 1-7, in some example embodiments, the location information of the lighting devices 102-120 may be used along with size and location information of other objects (e.g., walls, doors, windows, stairs, furniture, etc.) to generate the floor plan 700. For example, the size and location information of other objects may be determined by the AR device 200 executing AR operations (e.g., spatial mapping) and/or artificial intelligence applications that identify objects, surfaces, etc. To illustrate, a user may walk around the space 140 of FIG. 1 holding the AR device 200 while the AR device 200 executes AR and other applications based on inputs from various hardware and software components of the AR device 200.

In some example embodiments, various hardware and software components of the AR device 200 may be involved in identifying structures, objects, surfaces, and intelligent light fixtures to dynamically generate a three-dimensional representation of a given space, such as the space 140. For example, the various hardware and software components of the AR device 200 may include GPS or indoor positioning system components, a magnetometer, image recognition processor(s), depth sensing camera, spatial mapping software modules, etc. Along with the location information of the lighting devices 102-120 determined manually (as described with respect to FIG. 5) or using the lighting device markers 502, 504, etc. (as described with respect to FIG. 6), the size and location information of structures, objects, surfaces, etc. identified and determined by the AR device 200 may be used to generate the floor plan 700 of the space 140. In some example embodiments, the floor plan 700 may be used to properly commission the lighting system 100 installed in the space 140, for maintenance support of the lighting system 100, etc.

In some alternative embodiments, the floor plan 700 may not show furniture and other objects that are not integral structures of a building. In some alternative embodiments, the floor plan 700 may show objects using generic shapes without departing from the scope of this disclosure.

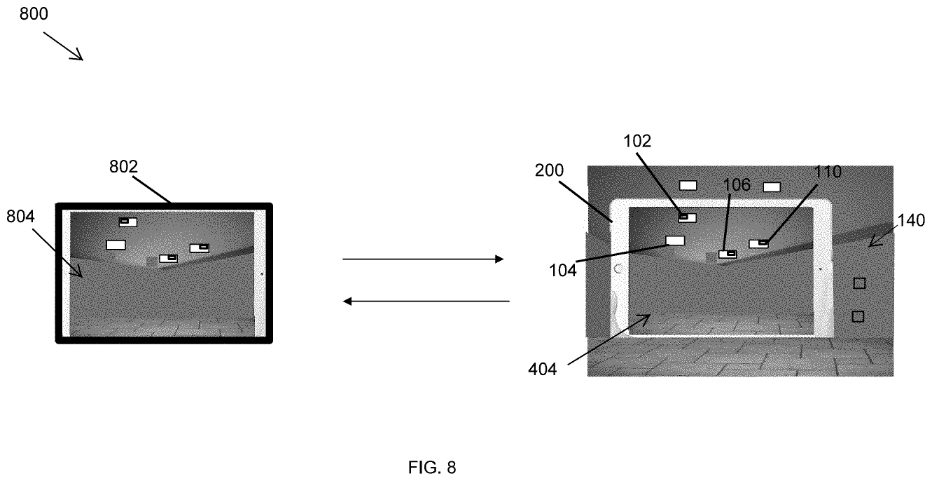

FIG. 8 illustrates a system for remote commissioning of the lighting system 100 of FIG. 1 according to an example embodiment. Referring to FIGS. 1-8, in some example embodiments, the AR device 200 may display the real time image 404 of the space 140 on the viewport 206 of the AR device 200 as described above. The AR device 200 may also transmit the real-time image 404 to a remote commissioning device 802. The remote commissioning device 802 may be a desktop, a laptop, a tablet, a smartphone, etc. The remote commissioning device 802 may receive the real time image 404 from the AR device 200 and display a real time image 804 corresponding to the real time image 404 on the display screen of the remote commissioning device 802.

In some example embodiments, the AR device 200 may also transmit to the remote commissioning device 802 location information of the lighting devices 102, 104, 106, 110 and spatial information of the portion of the space 140 displayed in the viewport 206. For example, the AR device 200 may transmit location information in association with the respective identification information of the lighting devices 102, 104, 106, 110. The spatial information may include information such as the height of the ceiling in the portion of the space 140 displayed in the viewport 206. As the real time image displayed on the viewport 206 changes, the AR device 200 may continue to transmit to the remote commissioning device 802 the real time image displayed in the viewport 206 and location information of lighting devices that appear in the real time image along with identification information of the lighting devices. The AR device 200 may also continue to send spatial information of the portion of the space 140 that is displayed in the viewport 206.

In some example embodiments, the remote commissioning device 802 may generate commissioning information based on the information received from the AR device 200. For example, the remote commissioning device 802 may determine illuminance values based on photometric files (e.g., IES files) corresponding to the lighting devices in the real time images 404, 804. To illustrate, the remote commissioning device 802 may use the received spatial information to calculate illuminance values at the floor level of the space 140. The photometric files may be stored in or retrievable by the remote commissioning device 802 from a server. The remote commissioning device 802 may also use the location information of the lighting devices and the spatial information along with the respective photometric files to determine combined illuminance values with respect to multiple lighting devices that may be located in close proximity to each other.

In some example embodiments, the commissioning information generated by the remote commissioning device 802 may include lighting fixture grouping information, lighting fixture and sensor grouping information, brightness level information (e.g., default brightness levels of lights provided by lighting fixtures of the system 100,), etc. that are determined by the remote commissioning device 802 based on one or more of the real time image, the lighting device location information, and the spatial information received from the AR device 200. For example, the remote commissioning device 802 may determine the grouping of lighting fixtures based on the illuminance values calculated with respect to the lighting devices and the locations of the lighting devices. As another example, the remote commissioning device 802 may determine the grouping of lighting fixtures with one or more of the sensors 112, 114 (shown in FIG. 1) based on the locations of the lighting fixtures and the sensors. For example, the locations of the lighting devices may be determined as described above, for example, with respect to FIGS. 5 and 6.

In some example embodiments, some of the operations performed by the remote commissioning device 802 may be performed in response to inputs from a commissioning expert at the remote commissioning device 802. For example, the commissioning expert may interact (e.g., using voice, text, etc.) with a person at the space 140 to direct the person to orient the AR device 200 in a particular direction, to capture particular lighting devices in the real time image 404, to confirm that all lighting devices in the lighting system 100 have been captured in the real time image, etc. In some example embodiments, using the device 802, the commissioning expert may control the commissioning process directly through a “passthrough” application of the remote commissioning device 802 that communicates with the AR application, the lighting control application, etc. that are executed by the AR device 200.

In some example embodiments, the commissioning expert may make use of the floor plans generated as described above with respect to FIGS. 6 and 7 to generate the commissioning information. For example, the floor plans may provide the commissioning expert an overall view of the space 140 and the locations of lighting devices and/or other objects and structures.

In some example embodiments, the commissioning expert may use the commissioning information (e.g., grouping, brightness level, etc.) to remotely perform the commissioning of the lighting system 100. For example, using the remote commissioning device 802, the commissioning expert may remotely access and configure the coordinator device 122, individual lighting devices, etc. of the lighting system 100. Alternatively, using the remote commissioning device 802, the commissioning expert may transmit the commissioning information to the person at the space 140 that can use the commissioning information to configure the lighting system 100. For example, the AR device 200 may receive the commissioning information, and the person at space 140 may use the AR device 200 to configure the coordinator device 122, individual lighting devices, etc. of the lighting system 100 using the commissioning information.

By using the information gathered and/or determined by the AR device 200, a commissioning expert may remotely commission the lighting system 100 without the need to travel to the location of the space 140. The remote commissioning system 800 may allow a remote commissioning expert to work with a non-expert located at the space 140 to perform the commissioning of the lighting system 100. In some cases, the remote commissioning of lighting systems may save time and expense associated with local commissioning.

In some alternative embodiments, an AR device other than the AR device 200 may be used at the space 140.

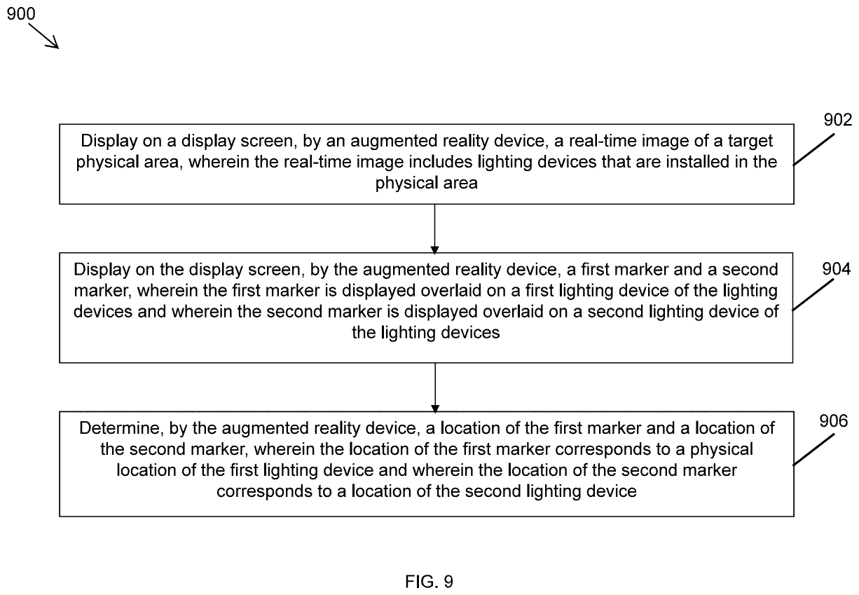

FIG. 9 illustrates a method 900 of determining locations of lighting devices using an AR device according to an example embodiment. Referring to FIGS. 1-6 and 9, in some example embodiments, at step 902, the method 900 includes displaying on a display screen, by an augmented reality device (e.g., the AR device 200), a real-time image of a target physical area (e.g., the space 140), where the real-time image includes lighting devices (e.g., lighting devices 102-120) that are installed in the physical area.

At step 904, the method 900 may include displaying on the display screen, by the augmented reality device, a first marker (e.g., the lighting device marker 502) and a second marker (e.g., the lighting device marker 602). The first marker is displayed overlaid on a first lighting device (e.g., the lighting fixture 102) of the lighting devices, and the second marker is displayed overlaid on a second lighting device (e.g., the lighting fixture 104) of the lighting devices. As described above with respect to FIG. 5, the first marker and the second marker may be displayed in the viewport 206 of the AR device 200, and a user may select and place the markers on the respective lighting devices associated with the markers.

At step 906, the method 900 may include determining, by the augmented reality device, a location of the first marker and a location of the second marker. Because the first marker is overlaid on the first lighting device, the location of the first marker corresponds to a physical location of the first lighting device. Because the second marker is overlaid on the second lighting device, the location of the second marker corresponds to a location of the second lighting device.

In some alternative embodiments, the method 900 may include other steps without departing from the scope of this disclosure.

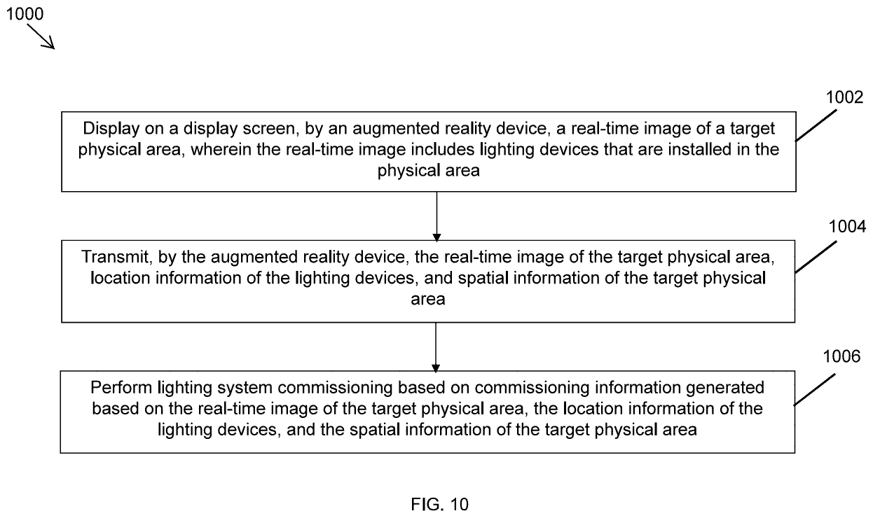

FIG. 10 illustrates a method 1000 of commissioning lighting system according to an example embodiment. Referring to FIGS. 1-10, in some example embodiments, at step 1002, the method 1000 includes displaying on a display screen, by an augmented reality device (e.g., the AR device 200), a real-time image of a target physical area (e.g., the space 140). The real-time image may include lighting devices (e.g., lighting devices 102-120) that are installed in the physical area.

At step 1004, the method 1000 may include transmitting, by the augmented reality device, the real-time image of the target physical area, location information of the lighting devices, and spatial information of the target physical area to a remote commissioning device (e.g., the remote commissioning device 802). For example, the location information of the lighting devices may be determined as described with respect to FIGS. 5 and 6. The AR device may determine spatial information of the target physical area as described above.

At step 1006, the method 1000 may include performing lighting system commissioning based on commissioning information generated based on the real-time image of the target physical area, the location information of the lighting devices, and the spatial information of the target physical area. For example, the AR device 200 may receive the commissioning information and perform the commissioning (e.g., configuring the coordinator device 112) of the lighting system 100.

In some alternative embodiments, the method 1000 may include other steps without departing from the scope of this disclosure.

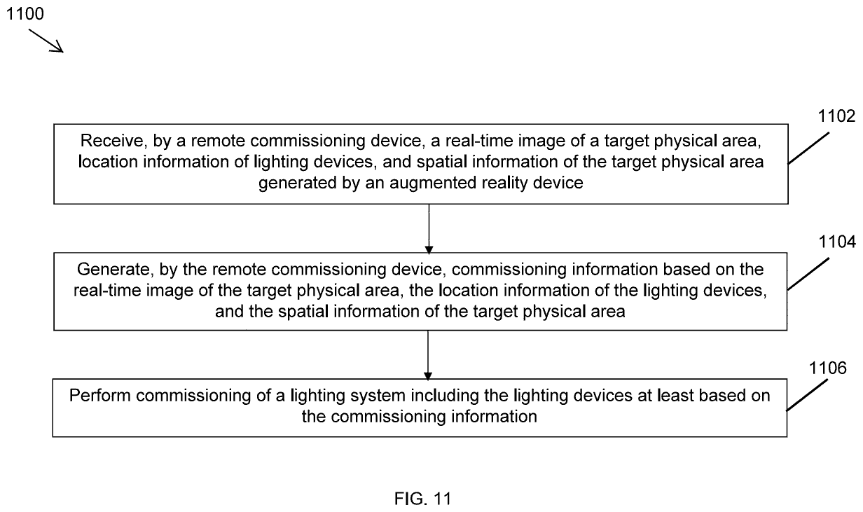

FIG. 11 illustrates a method 1100 of commissioning lighting system according to an example embodiment. Referring to FIGS. 1-11, in some example embodiments, at step 1102, the method 1100 includes receiving, by a remote commissioning device (e.g., the device 802), a real-time image of a target physical area (e.g., the space 140), location information of lighting devices (e.g., lighting devices 102-120), and spatial information of the target physical area generated by an augmented reality device (e.g., the AR device 200).

At step 1104, the method 1100 may include generating, by the remote commissioning device, commissioning information based on the real-time image of the target physical area, the location information of the lighting devices, and the spatial information of the target physical area. At step 1106, the method 1100 may include performing commissioning of a lighting system (e.g., the lighting system 100) including the lighting devices at least based on the commissioning information. For example, the remote commissioning device 802 may perform the commissioning (e.g., configuring the coordinator device 112) of the lighting system 100.

In some alternative embodiments, the method 1100 may include other steps without departing from the scope of this disclosure.

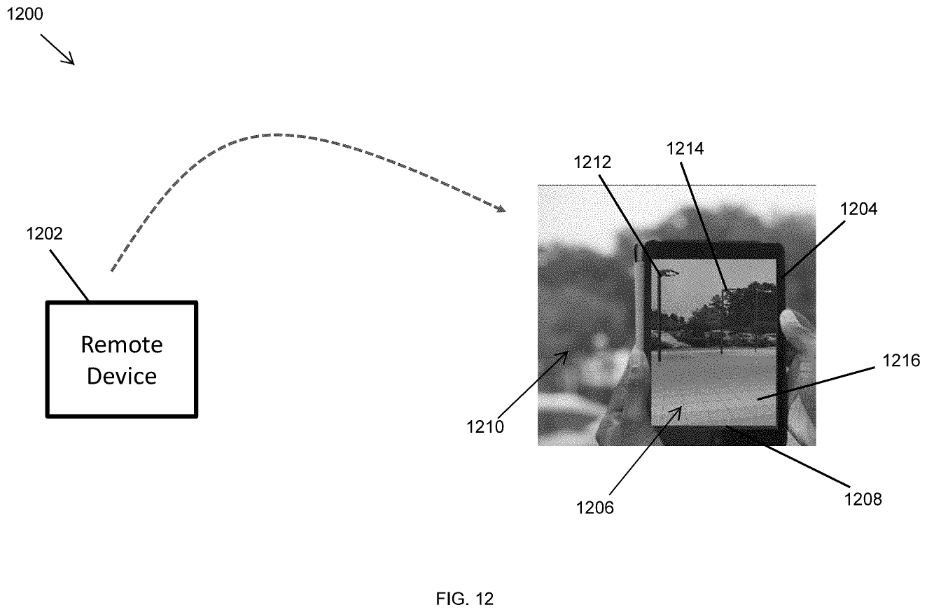

FIG. 12 illustrates an augmented reality-based lighting design system 1200 according to an example embodiment. In some example embodiments, the system 1200 includes a control/remote device 1202 and an AR device 1204. For example, the remote device 1202 may be a desktop, a laptop, a tablet, etc. The AR device 1204 may be a laptop, a tablet, a smartphone, etc. that can execute an AR application to display 3-D models in a viewport 1208 overlaid on a real time image of an area 1210. The AR device 1204 may also perform other operations such as determining the location (e.g., GPS location) of the AR device 1204 and/or identifying locations in an area 1210, calculating illuminance values, etc. The AR application may incorporate or interface with an AR software, such as ARKit, ARCore, Holokit, etc. to perform of the operations described herein with respect to the AR device 1204. In some example embodiments, the AR device 1204 may correspond to the AR device 200 or another AR device described above.

In some example embodiments, the system 1200 may be used to perform a lighting design of the area 1210. For example, the area 1210 may be an outdoor space such as a parking lot, a park, a walking trail, etc. Alternatively, the area 1210 may be an indoor space.

In some example embodiments, the control device 1202 may be located away from the area 1210, and the AR device 1204 may be located at the area 1210. To perform the lighting design of the area 1210, the control device 1202 may send to the AR device 1204 identification information of one or more lighting devices and respective location information for each lighting device. The identification information of a lighting device may include a serial number, a model number, and/or other identifying information that can be used by the AR device 1204. For example, the identification information of a lighting device may include information, such as name, size, color, type, etc. of the lighting device. The location information of a lighting device may indicate a physical location in the area 1210 at which a 3-D model of the lighting device should be augmented over the real time image of the area 1210.

In some example embodiments, the AR device 1204 may display 3-D models of lighting devices overlaid on a real time image 1206 of the area 1210 displayed on the viewport 1208. For example, 3-D models of various types of lighting devices may be stored in the AR device 1204, and the AR device 1204 may access a 3-D model of a lighting device that is identified by the received identification information and display the 3-D model on the viewport 1208 overlaid on the real time image 1206 of the area 1210.

In some example embodiments, the AR device 1204 may display the 3-D model such that the 3-D model is augmented over the real time image 1206 at a physical location of the area 1210 indicated by the location information received from the control device 1202. For example, the location information may include GPS coordinates or other location indicating information (e.g., direction and distance relative to a reference location).

To illustrate, an application engineer or a designer who is at a different location from the area 1210 may control the control device 1202 to transmit to the AR device 1204 identification information of a lighting device (e.g., an outdoor lighting fixture) and location information (e.g., GPS coordinates). For example, the identification information and the location information may be transmitted by the control device 1202 in association with each other as can be readily understood by those of ordinary skill in the art with the benefit of this disclosure. The information may be transmitted to the AR device 1204 in one or more formats, such as a link, one or more files, etc. that can be accessed or executed by the AR device 1204.

In some example embodiments, the AR device 1204 may receive the identification information and the location information and execute an AR application to display a 3-D model 1212 of the lighting fixture overlaid on the real time image 1206. For example, a person (e.g., a customer) at the area 1210 may operate the AR device 1204 to execute the AR application by the AR device 1204. The AR device 1204 may display the 3-D model 1212 using the received location information such that the 3-D model 1212 appears at the location identified by the received location information. The 3-D model 1212 may remain anchored to the physical location such that the 3-D model 1212 is displayed on the viewport 1208 whenever the physical location of the area 1210 is displayed in the viewport 1208.

In some example embodiments, the control device 1202 may transmit to the AR device 1204 identification information of another lighting device (e.g., an outdoor lighting fixture) and different location information (e.g., GPS coordinates). For example, the identification information and the location information may be transmitted by the control device 1202 in association with each other as can be readily understood by those of ordinary skill in the art with the benefit of this disclosure. The AR device 1204 may receive the identification information and the location information and execute the AR application to display a 3-D model 1214 of the lighting fixture overlaid on the real time image 1206. The AR device 1204 may display the 3-D model 1214 such that the 3-D model 1214 appears at the location identified by the received location information. The 3-D model 1214 may remain anchored to the physical location such that the 3-D model 1214 is displayed on the viewport 1208 whenever the physical location of the area 1210 is displayed in the viewport 1208.

In some example embodiments, the AR device 1204 may calculate illuminance values based on photometric files (e.g., IES files) corresponding to the lighting devices identified by the identification information. For example, photometric files for different types of lighting devices may be stored in the AR device 1204 or may be accessible by the AR device 1204 from a server such as a cloud server. For each lighting device indicated by the identification information, the AR device 1204 may access the respective photometric data and other information (e.g., height of the lighting device) to calculate the illuminance information, for example, at the ground level.

In some example embodiments, the AR device 1204 may display calculated illuminance values in the viewport 1208 overlaid on the real time image 1206. Alternatively or in addition, the AR device 1204 may display on the viewport 1208 a heat map 1216 overlaid on the real time image 1206, where the heat map 1216 is generated from the calculated illuminance values. For example, different colors of the heat map 1216 may indicate different illuminance levels as can be readily understood by those of ordinary skill in the art with the benefit of this disclosure.

In some example embodiments, a user operating the AR device 1204 may remove one or more of the 3-D models 1212, 1214, etc. from the viewport 1208. The AR device 1204 may receive identification information and location information for one or more additional lighting devices and execute the AR application to display respective 3-D models that are overlaid on the real time image 1206 at locations corresponding and anchored to physical locations indicated by the received location information.

The system 1200 enables a remotely located person (e.g., an engineer) to quickly and effectively demonstrate appearances of lighting devices in an area without having to be physically present at the area and without having to install lighting devices. The system 1200 also enables a remotely located person to perform lighting design without having to be physically present at the area.

In some alternative embodiments, the control device 1202 may be located at the same location as the AR device 1204 and may transmit information to the AR device 1204 as described above without departing from the scope of this disclosure. In some alternative embodiments, 3-D models of other types of lighting fixtures than shown may be displayed. In some example embodiments, the control device 1202 may transmit to the AR device 1204 identification information and associated location information for multiple lighting fixtures.

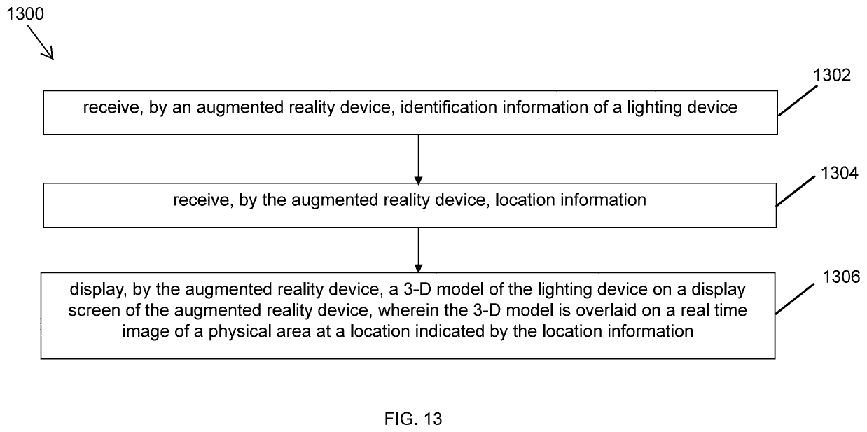

FIG. 13 illustrates an augmented reality-based lighting design method 1300 according to an example embodiment. Referring to FIGS. 12 and 13, in some example embodiments, at step 1302, the method 1300 includes receiving, by an augmented reality device (e.g., the AR device 1204), identification information of a lighting device. At step 1304, the method 1300 may include receiving, by the augmented reality device, location information, for example, from the remote device 1202.

At step 1306, the method 1300 may include displaying, by the augmented reality device, a 3-D model of the lighting device (e.g., the 3-D model 1212) on a display screen (e.g., the viewport 1208) of the augmented reality device. The 3-D model may be displayed overlaid on a real time image (e.g., the real time image 1206) of a physical area (e.g., the area 1210) at a location indicated by the location information.

In some alternative embodiments, the method 1100 may include other steps without departing from the scope of this disclosure.

Referring to FIGS. 4-13, in some alternative embodiments, an AR device other than the AR device 200 and the AR device 1202 may perform some of the operations described herein with respect to the AR device 200 and the AR device 1202. In some example embodiments, the above description referring to augmented reality may be equally applicable to mixed reality.

In some example embodiments, a non-transitory computer-readable medium (e.g., the memory device 312) of an augmented reality device (e.g., the AR device 200) contains instructions executable by a processor. The instructions include displaying on a display screen a real-time image of a target physical area, wherein the real-time image includes lighting devices that are installed in the physical area; displaying on the display screen a first marker and a second marker, wherein the first marker is displayed overlaid on a first lighting device of the lighting devices and wherein the second marker is displayed overlaid on a second lighting device of the lighting devices; and determining a location of the first marker and a location of the second marker. The first marker is associated with identification information of the first lighting device and wherein the second marker is associated with identification information of the second lighting device. The instructions further include displaying on the display screen, by the augmented reality device, a list of markers associated with to the lighting devices. The location of the first marker and the location of the second marker may be global positioning system (GPS) locations. The instructions further include identifying the first marker on the display screen in response to a user input.

Although particular embodiments have been described herein in detail, the descriptions are by way of example. The features of the example embodiments described herein are representative and, in alternative embodiments, certain features, elements, and/or steps may be added or omitted. Additionally, modifications to aspects of the example embodiments described herein may be made by those skilled in the art without departing from the scope of the following claims, the scope of which are to be accorded the broadest interpretation so as to encompass modifications and equivalent structures.

What is claimed is:

1. A method for determining locations of lighting devices, comprising:
displaying on a display screen, by an augmented reality device, a real-time image of a target physical area, wherein the real-time image includes lighting devices that are installed in the target physical area;
displaying on the display screen, by the augmented reality device, a first marker and a second marker, wherein the first marker is displayed overlaid on a first lighting device of the lighting devices and wherein the second marker is displayed overlaid on a second lighting device of the lighting devices; and
determining, by the augmented reality device, a location of the first marker and a location of the second marker.

2. The method of claim 1, wherein the first marker is associated with identification information of the first lighting device and wherein the second marker is associated with identification information of the second lighting device.

3. The method of claim 1, further comprising displaying on the display screen, by the augmented reality device, a list of markers corresponding to the lighting devices.

4. The method of claim 3, wherein selecting the first marker from the list of markers causes the first lighting device to provide one or more of a first visual indication or a first audio indication and wherein selecting the second marker from the list of markers causes the second lighting device to provide one or more of a second visual indication or a second audio indication.

5. The method of claim 3, wherein the first marker is identified on the display screen in response to a user input provided to the first lighting device.

6. The method of claim 3, wherein the first marker is displayed overlaid on the first lighting device in response to a first user input provided to the augmented reality device associating the first marker with the first lighting device displayed on the display screen and wherein the second marker is displayed overlaid on the second lighting device in response to a second user input provided to the augmented reality device associating the second marker with the second lighting device displayed on the display screen.

7. The method of claim 1, wherein the first marker is overlaid on a sensor of the first lighting device displayed on the display screen and wherein the second marker is overlaid on a sensor of the second lighting device displayed on the display screen.

8. The method of claim 1, wherein the location of the first marker and the location of the second marker are global positioning system (GPS) locations.

9. The method of claim 1, wherein the location of the first marker and the location of the second marker are determined based on a reference location in the target physical area.

10. The method of claim 1, wherein the first marker is associated with a wireless network address of the first lighting device and wherein the second marker is associated with a wireless network address of the second lighting device.

11. A method for commissioning a lighting system, the method comprising:
displaying on a display screen, by an augmented reality device, a real-time image of a target physical area that includes lighting devices;
transmitting, by the augmented reality device, the real-time image of the target physical area, location information of the lighting devices, and spatial information of the target physical area to a remote commissioning device; and
performing, by the remote commissioning device, lighting system commissioning of the lighting system based on commissioning information generated by the remote commissioning device based on at least the real-time image of the target physical area, the location information of the lighting devices, and the spatial information of the target physical area.

12. The method of claim 11, further comprising performing, by the augmented reality device, spatial mapping of the target physical area, wherein the spatial information includes a height of a ceiling in the target physical area.

13. The method of claim 11, further comprising determining, by the augmented reality device, locations of the lighting devices.

14. The method of claim 11, further comprising determining, by the remote commissioning device, illuminance values associated with the lighting devices, wherein the commissioning information is generated based on the illuminance values.

15. The method of claim 14, wherein the illuminance values are determined based on photometric profiles of the lighting devices.

16. The method of claim 11, wherein the commissioning information includes lighting device grouping information.

17. A method comprising:
receiving, by an augmented reality device, identification information of a lighting device from a remote device;
receiving, by the augmented reality device, location information from the remote device; and
displaying, by the augmented reality device, a 3-D model of the lighting device on a display screen of the augmented reality device, wherein the 3-D model is overlaid on a real time image of a physical area at a location indicated by the location information.

18. The method of claim 17, further comprising calculating, by the augmented reality device, illuminance values based on photometric data corresponding to the lighting device.

19. The method of claim 18, further comprising displaying the illuminance values overlaid on the real time image of the physical area.

20. The method of claim 18, further comprising displaying a heat map overlaid on the real time image of the physical area, wherein the heat map corresponds to the illuminance values.
